(19) United States
(12) Patent Application Publication
(10) Pub. No.: US 2013/0069067 A1
(43) Pub. Date: Mar. 21, 2013

(54) ORGANIC LIGHT EMITTING DIODE (OLED) DISPLAY DEVICE AND METHOD FOR MANUFACTURING THE SAME

(71) Applicant: Keun Chun Youn, Paju-si (KR)

(72) Inventor: Keun Chun Youn, Paju-si (KR)

(21) Appl. No.: 13/237,381

(22) Filed: Sep. 20, 2011

(51) Int. Cl. H01L 51/52; H01L 51/56

(52) U.S. Cl. 257/59; 257/72; 438/34; 257/40; 257/E51.018

(57) ABSTRACT

The present invention relates to an organic light emitting diode (OLED) display device and a manufacturing method thereof. An object of the present invention is to provide an organic light emitting diode (OLED) display device and a manufacturing method thereof, in which an auxiliary electrode is formed between a substrate and a second electrode of an OLED cell so as to be connected with the second electrode, thereby improving the luminance uniformity of a large-area the OLED display device, and enabling the quality improvement and economic manufacture of products adopting the OLED display device.

### BACKGROUND OF THE INVENTION

1. Field of the Invention

Exemplary embodiments of the present invention relate to an organic light emitting diode (OLED) display device and a manufacturing method thereof, and more particularly, to an organic light emitting diode (also, called “OLED”) display device and a manufacturing method thereof, in which the luminance uniformity of a large-area OLED display device is improved through a simple structure improvement of the OLED display device so as to enable the quality improvement and economic manufacture of products adopting the OLED display device.

2. Description of Related Art

Recently, an interest in flat panel display (FPD) devices grows increasingly, and examples of such FPD devices include liquid crystal displays (LCDs), plasma display panels (PDPs), field emission displays (FEDs), electroluminescence (also called “EL”) display devices, and the like.

Among them, the EL display devices are self-emissive display devices that have features of a high response speed, increased luminous efficiency and high luminance, and a wide viewing angle. In addition, the EL display device is largely classified into an inorganic EL display device and an organic EL display device depending on a material of an emissive layer. The inorganic EL display device has a larger power consumption and a lower luminance as compared to an organic EL display device, which is called an organic electroluminescence display device or an organic light emitting diode (OLED) display device. In addition, the inorganic EL display device cannot emit light of various colors such as red (R), green (G), and blue (B). On the other hand, the organic EL display device is driven at a low voltage more or less than 10V, has a high response speed, and can obtain a high luminance (brightness). In addition, the organic EL display device is the most suitable for a next generation flat panel display (FPD) as being capable of emitting light of various colors such as red (R), green (G), and blue (B).

FIG. 1 shows an example of a top emission type organic light emitting diode (OLED) display device as one of various constitutions of a conventional organic light emitting diode (OLED) display device according to the prior art and a thin film transistor (TFT).

As shown in FIG. 1, the top emission type OLED display device includes a unit pixel 60 arranged respectively in a region defined by the intersection of each of gate lines GL and each of data lines DL. When a gate pulse is supplied to the gate line GL, the unit pixel 60 receives a data signal from the data line DL so that the OLED display device emits light to display images in response to the data signal. In addition, a number of unit pixels gather to constitute a display element region.

In the meantime, the unit pixel 60 includes an OLED cell whose second electrode is connected to a driving voltage source VDD, and a cell-driving part 62 which is connected to the gate line GL, the data line DL, the ground voltage source GND, the first electrode of the OLED cell, and a first electrode of the OLED cell. The cell-driving part 62 includes a switching thin film transistor (TFT) (hereinafter, referred to as “TFT”) T1, a driving TFT T2, and a capacitor C.

The switching TFT T1 is turned on when the gate pulse is supplied to the gate line GL, and applies the data signal supplied to the data line DL to a node N. A voltage corresponding to the data signal applied to the node N is charged in the capacitor C and is supplied to a gate electrode of the driving TFT T2.

The driving TFT T2 controls the amount of current supplied to the OLED cell from the driving voltage source VDD in response to the data signal supplied to the gate electrode thereof so as to adjust the amount of light emitted from the OLED cell. In addition, although the switching TFT T1 is turned off, the data signal is maintained by the capacitor C. At this time, until a data signal of a next frame is supplied, the driving TFT T2 supplies current I to the OLED cell from the driving voltage source VDD to maintain the light emission of the OLED cell.

FIG. 2 is a cross-sectional view illustrating a partial region of a unit pixel of the OLED display device shown in FIG. 1;

Referring to FIG. 2, the conventional organic light emitting diode (OLED) display device includes the switching TFT T1 (see FIG. 1), the driving TFT T2 whose gate electrode 24 is connected to a drain electrode of the switching TFT, and the OLED cell whose first electrode 12 is connected to a drain electrode 28 of the driving TFT T2.

The switching TFT includes a gate electrode connected to the gate line GL (see FIG. 1), a source electrode connected to the data line DL (see FIG. 1), and a drain electrode connected to the gate electrode 24 of the driving TFT T2.

The driving TFT T2 includes a gate electrode 24 connected to the drain electrode of the switching TFT, a source electrode 26 connected to the ground voltage source GND, a drain electrode 28 connected to the first electrode 12 of the OLED cell, and an active layer 38 disposed between the source electrode 26 and the drain electrode 28 to form a channel therebetween.

In more detail, the driving TFT T2 includes the gate electrode 24 formed together with the gate line, the source and drain electrodes 26 and 28 formed together with the data line, the active layer 38 disposed between the source electrode 26 and the drain electrode 28 to form a channel therebetween with a gate insulating film 36 interposed between the gate electrode 24 and the active layer 38 in an overlapped manner, and an ohmic contact layer 40 for reducing a contact resistance between the active layer 38 and the source electrode 26/the drain electrode 28. Further, the driving TFT T2 includes a drain contact hole 34 formed by penetrating through a protective film 30 to expose the drain electrode 28 thereof in order to make the contact between the first electrode 12 of the OLED cell and the drain electrode 28 thereof.

The OLED cell includes an organic light-emitting layer 10, and a first electrode 12 and a second electrode 4, which are insulated from each other by an insulating film 6 and are formed on and beneath the organic light-emitting layer 10, respectively.

The second electrode 4 is formed of one or more layers of a transparent conductive material such as indium tin oxide (ITO), indium zinc oxide (IZO), and the like, or an opaque material such as aluminum (Al), an AlLi alloy, magnesium (Mg), calcium (Ca), silver (Ag), an MgAg alloy, and the like. The second electrode 4 is supplied with a driving signal from the driving voltage source VDD (see FIG. 1) to emit charges.

The first electrode 12 is connected with the drain electrode 28 of the driving TFT T2 through the drain contact hole 34, and is formed in each OLED cell region. The first electrode 12 is supplied with a driving signal from the drain electrode 28 of the driving TFT T2 to emit charges.

The organic light-emitting layer 10 is formed by sequentially depositing an electron injection layer 10a, an electron transport layer 10b, an emissive layer 10c, a hole transport layer 10d, and a hole injection layer 10e. The organic light-emitting layer 10 is supplied with charges from the first electrode 12 and the second electrode 4. Then, as shown in FIG. 3, the second electrode 4 discharges holes, which are in turn moved to the emissive layer 10c via the hole injection layer 10e and the hole transport layer 10d. In addition, the first electrode 12 discharges electrons, which are in turn moved to the emissive layer 10c via the electron injection layer 10a and the electron transport layer 10b so that the moved carriers, i.e., the holes and the electrons are re-combined in the emissive layer 10c to cause the organic light-emitting layer 10 to emit a visible light. At this time, the emitted visible light exits the second electrode 4 as a transparent electrode so that images are displayed on the OLED display device.

In the meantime, in order to increase the amount of the visible light emitted from the second electrode 4, the first electrode 12 may be formed of at least one of an aluminum-based metal including aluminum (Al), aluminum neodium (AlNd), and the like, Cr, a Cr alloy, and the like, which have a high reflectivity.

However, the above structure does not cause a problem in a conventional a small-area OLED display device does not encounters a problem, but a recently developed large-area OLED display device entails a problem in that in the case where current flows between a peripheral region and a central region through the second electrode 4, when current reaches a remote place from a place where the current is introduced, a voltage drop occurs due to a resistance of the second electrode, thereby resulting in a difference of luminance between the peripheral part and the central part as shown in FIG. 4. That is, for the large-area organic light emitting diode (OLED) display device, since the luminance uniformity is sharply deteriorated due to the difference of luminance between the peripheral part and the central part caused by the resistance of the second electrode. There is a need for a panel structure or driving means which can complement the luminance difference.

### SUMMARY OF THE INVENTION

Accordingly, the present invention has been made in an effort to solve the aforementioned problems occurring in the prior art, and it is an object of the present invention to provide a structure of an organic light emitting diode (OLED) display device and a manufacturing method thereof, in which an auxiliary electrode is formed between a substrate and a second electrode of an OLED cell so as to be connected with the second electrode, thereby improving the luminance uniformity of a large-area the OLED display device.

To accomplish the above object, according to one aspect of the present invention, there is provided an organic light emitting diode (OLED) display device, including: a substrate formed of any one of glass, metal, and plastic; a thin film transistor (TFT) formed on the substrate for driving the OLED display device; a display element region consisting of a group of unit pixels, each of which is defined by the intersection of each of data lines and each of gate lines of the thin film transistor (TFT); a first electrode formed on a top of the driving thin film transistor (TFT); an auxiliary electrode formed on the substrate; an opening formed by exposing a part of a top surface of the auxiliary electrode; a barrier rib formed on the opening of the auxiliary electrode; an organic light-emitting layer on the first electrode; a second electrode on the organic light-emitting layer; and a conductive layer formed on or beneath the second electrode so as to be a part of the second electrode, whereby the second electrode or the conductive layer is connected with the auxiliary electrode using the barrier rib to reduce a resistance of the second electrode.

Preferably, the auxiliary electrode may be formed between the substrate and the second electrode so as to be as a part of the driving TFT or as an independent wiring.

In addition, preferably, the opening may be formed over a part or the whole of the pixels of the display element region.

In addition, preferably, the barrier rib may be formed at at least one part thereof in an inverted trapezoidal (or tapered) shape which is gradually increased in width as it goes toward the top from the bottom thereof.

Further, preferably, the barrier rib may be formed in an inverted trapezoidal (or tapered) shape of a two or more-layered structure, or may be formed to have a two or more-layered structure in which a top layer has an overhang shape (i.e., T shape).

Also, preferably, at least one barrier rib may be formed on each opening of the auxiliary electrode.

Moreover, preferably, the second electrode may be directly connected with the auxiliary electrode without forming the conductive layer using the sputtering or the chemical vapor deposition (CVD).

In addition, preferably, in the case where the second electrode is formed by a thermal evaporation, the second electrode may be indirectly connected with the auxiliary electrode by forming the conductive layer using the sputtering or the chemical vapor deposition (CVD).

Besides, preferably, in the case where the second electrode is formed by a thermal evaporation method, the second electrode may be deposited by inclining the substrate such that the second electrode is deposited on the empty space of the barrier rib so as to be connected with the auxiliary electrode.

According to another aspect of the present invention, there is provided a method for manufacturing an organic light emitting diode (OLED) display device, including: 1) forming a substrate formed of any one of glass, metal, and plastic, and a thin film transistor (TFT) formed on the substrate for driving the OLED display device; 2) forming a first electrode on a top of the driving TFT; 3) forming an auxiliary electrode on the substrate and exposing a part of a top surface of the auxiliary electrode to form an opening; 4) forming a barrier rib on the opening of the auxiliary electrode; 5) forming an organic light-emitting layer on the first electrode; 6) forming a second electrode on the organic light-emitting layer; and 7) forming a conductive layer on or beneath the second electrode so as to be a part of the second electrode, if necessary.

Terms and words used in the detailed description and the claims should not be construed as a typical or dictionary meaning, but should be interpreted as the meaning and concept conforming to the technical idea of the present invention based on the principle that the inventor can properly define the concept of the terms to explain his or her invention in the best way.

### BRIEF DESCRIPTION OF THE DRAWINGS

The above and other objects, features and advantages of the present invention will be apparent from the following detailed description of the preferred embodiments of the invention when taken in conjunction with the accompanying drawings, in which:

FIG. 1 is a circuit diagram equivalently illustrating a conventional organic light emitting diode (OLED) display device according to the prior art;

FIG. 2 is a cross-sectional view illustrating a partial region of the organic light emitting diode (OLED) display device shown in FIG. 1;

FIG. 3 is a diagrammatic view illustrating a luminescence principle of the conventional organic light emitting diode (OLED) display device;

FIG. 4 is a top plan view illustrating a panel formed from a typical organic light emitting diode (OLED) display device according to the prior art;

FIG. 5 is a cross-sectional view illustrating an organic light emitting diode (OLED) display device according an exemplary embodiment of the present invention;

FIG. 6 is a process flow diagram illustrating a manufacturing method of an organic light emitting diode (OLED) display device of according an exemplary embodiment of the present invention;

FIGS. 7 to 12 are process charts illustrating a manufacturing method of an organic light emitting diode (OLED) display device according to an exemplary embodiment of the present invention;

FIG. 13 is a view illustrating modifications of a barrier rib in an organic light emitting diode (OLED) display device according to an exemplary embodiment of the present invention;

FIG. 14 is a cross-sectional view illustrating an organic light emitting diode (OLED) display device according an exemplary embodiment of the present invention in which a reflective plate is formed beneath a first electrode;

FIG. 15 is a cross-sectional view illustrating an organic light emitting diode (OLED) display device according an exemplary embodiment of the present invention in which the reflective plate of FIG. 14 is used as an auxiliary electrode;

FIG. 16 is a view illustrating an organic light emitting diode (OLED) display device according an exemplary embodiment of the present invention in which an opening and a barrier rib are formed on a TFT arrangement region as a non-emissive part;

FIG. 17 is a cross-sectional view illustrating a top emission type organic light emitting diode (OLED) display device according an exemplary embodiment of the present invention in which an opening and a barrier rib are formed below a BM as an upper non-light exiting region;

FIG. 18 is a table illustrating a change in the contact resistance between a second electrode and an auxiliary electrode according to the taper angle of the barrier rib;

FIG. 19 is a cross-sectional view illustrating an organic light emitting diode (OLED) display device according an exemplary embodiment of the present invention in which a protective thin film is formed on the barrier rib to prevent moisture or oxygen from infiltrating into the opening and a side of the barrier rib and deteriorating the OLED display device, thereby protecting the OLED display device; and

FIG. 20 is a cross-sectional view illustrating an organic light emitting diode (OLED) display device according an exemplary embodiment of the present invention in which a protective coating film as a substitute for the protective thin film is thickly formed on the barrier rib.

### DETAILED DESCRIPTION

An organic light emitting diode (OLED) display device and a manufacturing method thereof according to a preferred embodiment of the present invention will now be described in detail with reference to the accompanying drawings. It should be noted that the same elements or parts are denoted by the same reference numerals throughout the specification. Herein, a detailed description of a known function or configuration of the present invention in describing the spirit of the present invention will be omitted if it is deemed to obscure the subject matter of the present invention.

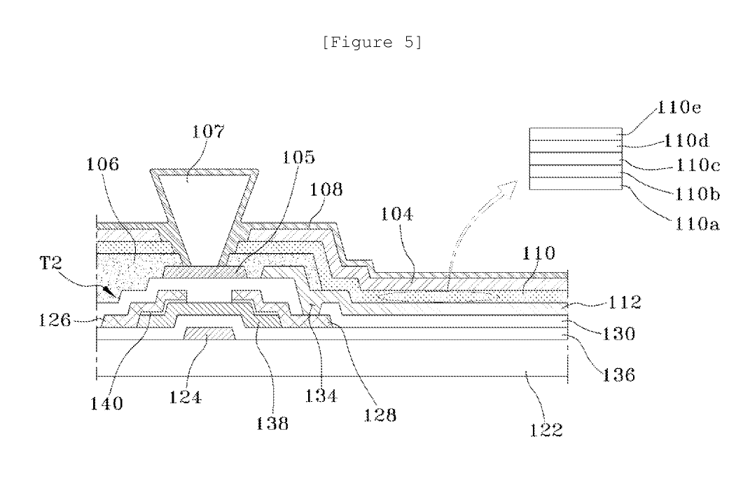

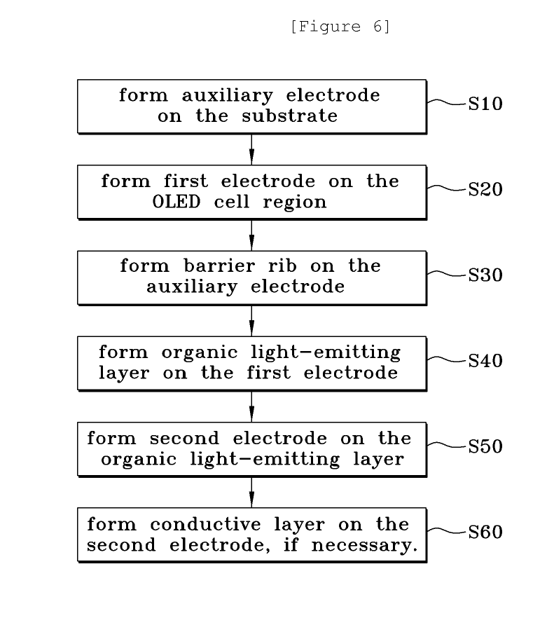

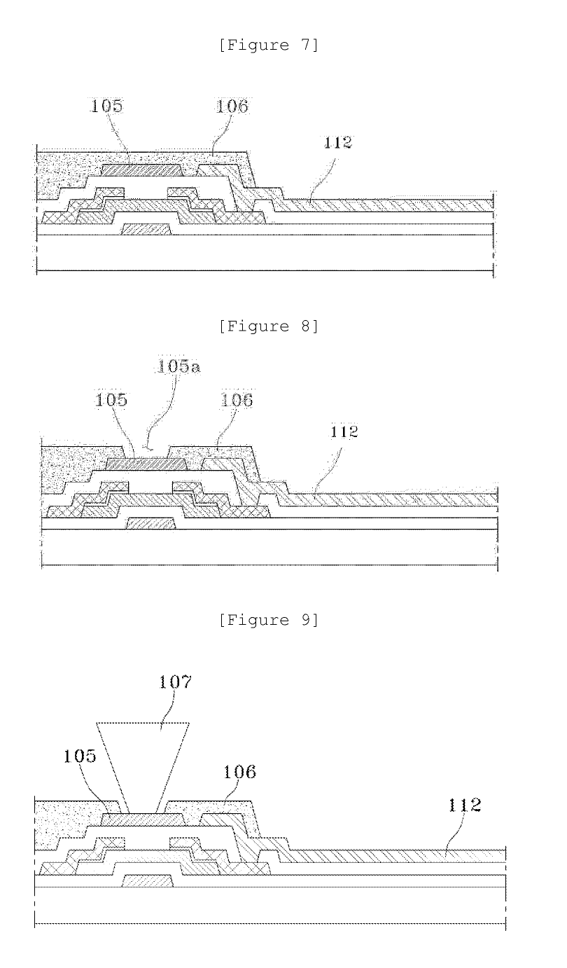

FIG. 5 is a cross-sectional view illustrating an organic light emitting diode (OLED) display device according an exemplary embodiment of the present invention, FIG. 6 is a process flow diagram illustrating a manufacturing method of an organic light emitting diode (OLED) display device of according an exemplary embodiment of the present invention, and FIGS. 7 to 12 are process charts illustrating a manufacturing method of an organic light emitting diode (OLED) display device according to an exemplary embodiment of the present invention.

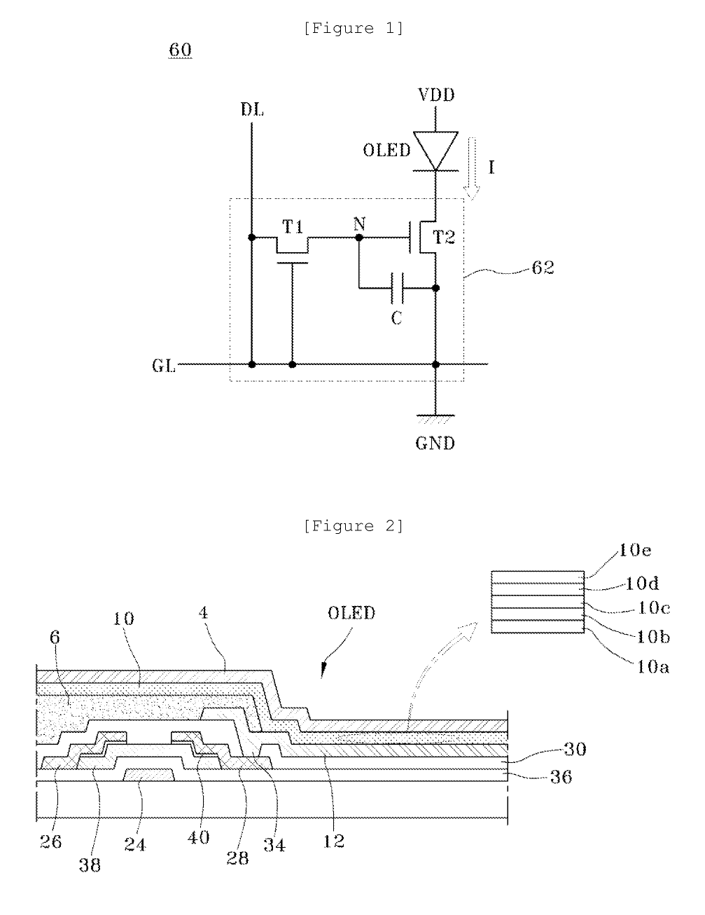

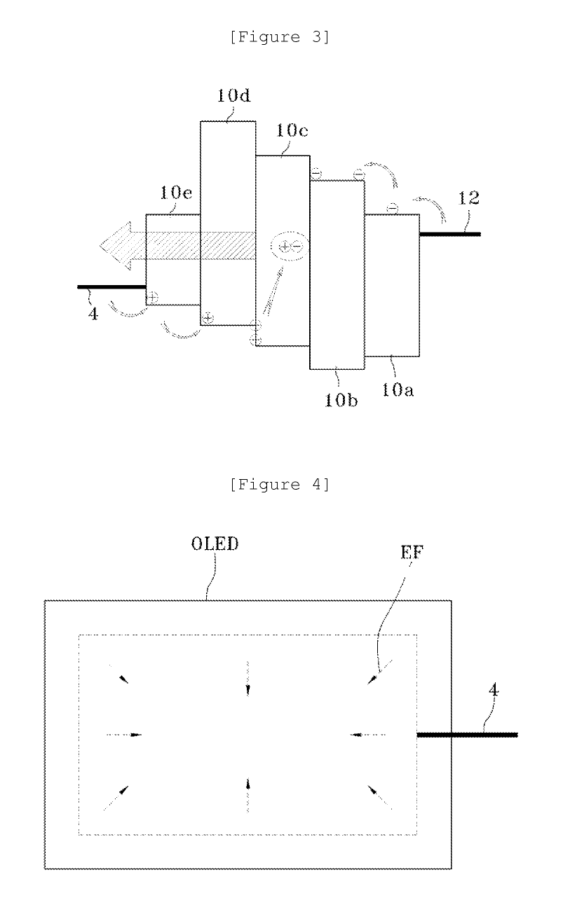

Referring to FIG. 5, the organic light emitting diode (OLED) display device according to exemplary embodiment of the present invention includes a switching TFT T1 (see FIG. 1), a driving TFT T2 whose gate electrode 124 is connected to a drain electrode of the switching TFT, and an OLED cell whose first electrode 112 is connected to a drain electrode 128 of the driving TFT T2.

An organic light-emitting layer 110 is formed by sequentially depositing an electron injection layer 110a, an electron transport layer 110b, an emissive layer 110c, a hole transport layer 110d, and a hole injection layer 110e. The organic light-emitting layer 110 is supplied with charges from the first electrode 112 and the second electrode 104. Then, the second electrode 104 discharges holes, which are in turn moved to the emissive layer 110c via the hole injection layer 110e and the hole transport layer 110d. In addition, the first electrode 112 discharges electrons, which are in turn moved to the emissive layer 110c via the electron injection layer 110a and the electron transport layer 110b so that the moved carriers, i.e., the holes and the electrons are re-combined in the emissive layer 110c to cause the organic light-emitting layer 110 to emit a visible light. At this time, the emitted visible light exits the second electrode 104 as a transparent electrode so that images are displayed on the OLED display device.

The switching TFT T1 includes a gate electrode connected to a gate line GL (see FIG. 1), a source electrode connected to a data line DL (see FIG. 1), and a drain electrode connected to a gate electrode 124 of the driving TFT T2.

The driving TFT T2 includes a gate electrode 124 connected to the drain electrode of the switching TFT, a source electrode 126 connected to the ground voltage source GND (see FIG. 1), a drain electrode 128 connected to the first electrode 112 of the OLED cell, and an active layer 138 disposed between the source electrode 126 and the drain electrode 128 to form a channel therebetween.

In more detail, the driving TFT T2 includes the gate electrode 124 formed together with the gate line, the source and drain electrodes 126 and 128 formed together with the data line, the active layer 138 disposed between the source electrode 126 and the drain electrode 128 to form a channel therebetween with a gate insulating film 136 interposed between the gate electrode 124 and the active layer 138 in an overlapped manner, and an ohmic contact layer 140 for reducing a contact resistance between the active layer 138 and the source electrode 126/the drain electrode 128.

Further, the driving TFT T2 includes a drain contact hole 134 formed by penetrating through a protective film 130 to expose the drain electrode 128 thereof in order to make the contact between the first electrode 112 of the OLED cell and the drain electrode 128 thereof. In addition, an auxiliary electrode 105 is formed on the driving TFT T2, and contacts with the second electrode 104 via a conductive layer 108 so as to be supplied with a driving signal. Also, a barrier rib 107 is further formed on the auxiliary electrode 105. Before the barrier rib 107 is formed on the auxiliary electrode 105, a top of the auxiliary electrode 105 is partially exposed to form an opening 105a so that the barrier rib 107 is formed in the opening 105a. At this time, the opening 105a of the auxiliary electrode may be formed over a partial pixel or entire pixel of the unit cell. The barrier rib 107 is formed in a tapered shape which is gradually increased in width it goes toward the top from the bottom thereof contacting with the top of the auxiliary electrode 105 so that an empty space is formed between the barrier rib and the organic light-emitting layer 110 upon the deposition of the organic light-emitting layer 110 on the first electrode 112. The reason for this is that an empty space is secured which is not coated with the organic light-emitting layer in a deposition step of the organic light-emitting layer in which the scattering of a material has a linearity upon the deposition of the organic light-emitting layer 110 so as to prevent the auxiliary electrode from being completely coated by the deposition of the organic light-emitting layer.

A conductive layer 108 is formed on the auxiliary electrode 105 and the second electrode 104, and is configured such that the auxiliary electrode 105 and the second electrode 104 are electrically conducted with each other by the conductive layer 108. In this case, the conductive layer 108 is filled in the empty space formed around the barrier rib as mentioned above.

The conductive layer 108 is filled in the empty space by using sputtering, chemical vapor deposition (CVD) or glancing-angle deposition, which has an excellent step coverage of a thin film.

The OLED cell includes the organic light-emitting layer 110, and the first electrode 112 and a second electrode 104, which are insulated from each other by an insulating film 106 and are formed on and beneath the organic light-emitting layer 110, respectively.

The second electrode 104 is formed of a transparent conductive material. The second electrode 104 is supplied with a driving signal from the driving voltage source VDD (see FIG. 1) to emit holes.

The first electrode 112 is connected with the drain electrode 128 of the driving TFT T2 through the drain contact hole 134, and is formed in each OLED cell region. In addition, the first electrode 112 is supplied with a driving signal from the drain electrode 128 of the driving TFT T2 to emit electrons.

The organic light-emitting layer 110 is formed by sequentially depositing an electron injection layer 110a, an electron transport layer 110b, an emissive layer 110c, a hole transport layer 110d, and a hole injection layer 110e. In addition, when the organic light-emitting layer 110 is supplied with the driving signals from the first electrode 112 and the second electrode 104, holes discharged from the second electrode 104 and electrons discharged from the first electrode 112 are re-combined in the emissive layer 110c to cause the organic light-emitting layer 110 to emit a visible light. At this time, the emitted visible light exits the second electrode 104 as a transparent electrode so that images are displayed on the OLED display device. Likewise, the auxiliary electrode and the OLED second electrode are connected to each other by the conductive layer so that electric current can be transferred uniformly over the entire display element region owing to a decrease in a resistance of the second electrode and thus a reduction in a voltage drop by the auxiliary electrode, thereby improving luminance uniformity.

In the meantime, the barrier rib 107 is used as a means for preventing the organic light-emitting layer 110 from being deposited on the auxiliary electrode 105. The barrier rib is not formed when the organic light-emitting layer 110 is deposited on the first electrode 112, but the organic light-emitting layer 110 is deposited over up to the auxiliary electrode and then only the organic light-emitting layer 110 deposited on the auxiliary electrode is removed to partially expose a top surface of the auxiliary electrode. That is, as mentioned above, the barrier rib 107 is used as a means for preventing the organic light-emitting layer from completely coating the auxiliary electrode. In order to prevent the organic light-emitting layer from contacting with the auxiliary electrode, a barrier rib forming process may be replace with a removal process of the organic film of a relevant portion using an etching method employing a laser or a chemical means. However, it is a high possibility that the organic film will be deteriorated or damaged during the etching process, or contaminants will be remained in the organic film after the etching process, thereby having an adverse effect on the reliability of the OLED.

Meanwhile, in a preferred embodiment of the present invention, the auxiliary electrode 105 has a sheet resistance of from 0.01 to 50 Ω/sq, and the second electrode as a main electrode has a sheet resistance of from 0.1 to 10MΩ/sq.

In addition, in the present invention, in the case where the single second electrode or the second electrode including the conductive layer serves as a cathode, i.e., a negative (−) electrode, it may be configured to have a structure including at least one electrode layer whose electron transport material matches with the work function of the cathode. Also, in the case where the single second electrode or the second electrode including the conductive layer serves as an anode, i.e., a positive (+) electrode, it may be configured to have a structure including at least one electrode layer whose hole transport material matches with the work function of the anode.

A method for manufacturing the organic light emitting diode (OLED) display device according to a preferred embodiment of the present invention will be described hereinafter with reference to FIG. 6.

The method for manufacturing the organic light emitting diode (OLED) display device includes:

1) a step S10 of forming an auxiliary electrode on a substrate having an OLED cell region defined by the intersection of each of data lines and each of gate lines;

2) a step S20 of forming a first electrode on the OLED cell region;

3) a step S30 of forming a barrier rib on the auxiliary electrode;

4) a step S40 of forming an organic light-emitting layer on the first electrode;

5) a step S50 of forming a second electrode on the organic light-emitting layer;

6) a step S60 of forming a conductive layer on the second electrode to interconnect the auxiliary electrode and the second electrode through the conductive layer, if necessary.

In the step S10, the auxiliary electrode is formed at a specific position between a top of the substrate and the second electrode depending on the process or a substrate structure. In this case, in the step S30 of forming the barrier rib, the barrier rib is formed in such a fashion as to be increased gradually in width as it goes toward the top from the bottom thereof, and an empty space where the organic light-emitting layer is not deposited is formed below the barrier rib.

In the steps S50 and S60, the second electrode and conductive layer are formed by any one of sputtering, chemical vapor deposition (CVD), glancing-angle deposition, general deposition, and the like. In this embodiment, although the auxiliary electrode 105 is formed on the TFT after the TFT forming step, it may be formed before the TFT forming step or at an arbitrary position within the TFT layer. After the auxiliary electrode is formed, it is finally connected to the second electrode or the conductive layer by a proper means.

The manufacturing method of the organic light emitting diode (OLED) display device will be described in detail with reference to FIG. 7.

An aluminum-based metal containing aluminum (Al) and aluminum neodium (AlNd) is deposited and patterned on the entire top surface of a substrate 122 on which the switching TFT and the driving TFT T2 including a gate electrode 124, a gate insulating layer 136, an active layer 138, a source electrode 126, a drain electrode 128, an ohmic contact layer 140, so that the first electrode 112 is formed so as to connected with a drain electrode 128 of the driving TFT T2 through a drain contact hole 134. Subsequently, the auxiliary electrode 105 is deposited on the driving TFT T2. Herein, the auxiliary electrode 105 is preferably formed of the same material as that of the first electrode 112. In this case, the auxiliary electrode 105 is formed spaced apart from the driving TFT T2 by a predetermined distance.

Next, referring to FIG. 8, the auxiliary electrode 105 is deposited and patterned on the driving TFT T2, so that an insulating film 106 is formed in a state in which a part of the first electrode 112 on which the organic light-emitting layer 110 is to be formed and a part of the auxiliary electrode 105 on which the barrier rib 107 is to be formed are exposed to form an opening 105a. In this case, the opening 105 of the auxiliary electrode may be formed over a partial pixel or the entire pixel of a unit pixel of a display element region.

Then, referring to FIG. 9, the barrier rib 107 is formed on the exposed auxiliary electrode 105. The barrier rib 107 is formed in a tapered shape which is gradually increased in width it goes toward the top from the bottom thereof contacting with the top of the auxiliary electrode 105.

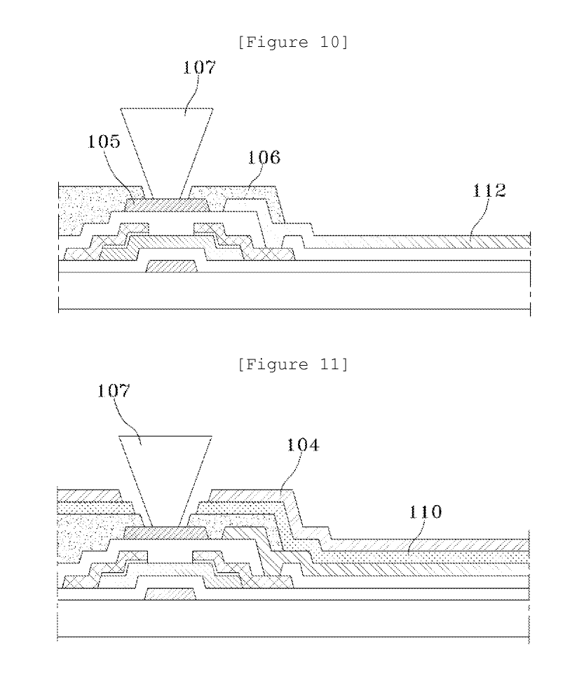

Next, referring to FIG. 10, an organic light-emitting material is deposited on the substrate 122 to form the organic light-emitting layer 110. Subsequently, as shown in FIG. 11, the second electrode 104 is formed of one or more layers of a transparent conductive material such as indium tin oxide (ITO), indium zinc oxide (IZO), and the like, or an opaque material such as aluminum (Al), an AlLi alloy, magnesium (Mg), calcium (Ca), silver (Ag), an MgAg alloy, and the like.

In this case, the barrier rib 107 is used to prevent the organic light-emitting layer 110 from completely coating the auxiliary electrode 105. That is, since the organic light-emitting layer 110 has a high linearity upon the deposition thereof, it cannot be deposited beneath the barrier rib, and thus an empty space is formed between the auxiliary electrode and the organic light-emitting layer through a tapered shape of the bottom and the top of the barrier rib.

The barrier rib 107 is used as a means for preventing the organic light-emitting layer 110 from being deposited on the auxiliary electrode 105. In the process of depositing the organic light-emitting layer 110 on the first electrode 112, after the organic light-emitting layer is coated on the top of the auxiliary electrode without using the barrier rib, only the organic light-emitting layer coated on the auxiliary electrode is partially removed through an etching process to expose a part of the top of the auxiliary electrode to enable the auxiliary electrode to be connected with the second electrode. That is, as mentioned above, the barrier rib 107 is a means for preventing the organic light-emitting layer from completely coating the auxiliary electrode. The etching process for preventing the organic light-emitting layer from contacting with the auxiliary electrode may be replaced with the barrier rib.

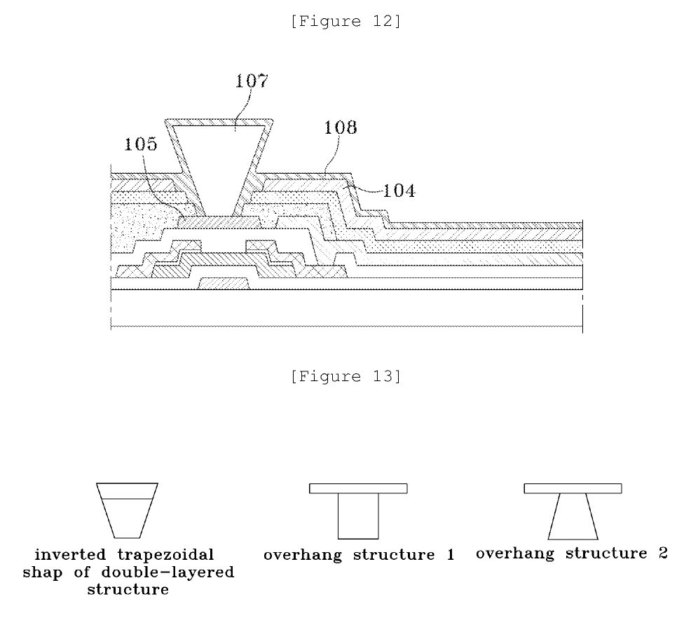

Subsequently, referring to FIG. 12, a conductive layer 108 is deposited on the second electrode 104 using any one selected from the sputtering and the chemical vapor deposition (CVD), and infiltrates into the empty space formed by the barrier rib to coat a part of the auxiliary electrode 105 so that the second electrode and the auxiliary electrode are connected to each other by the conductive layer 108.

In FIG. 12, the second electrode and the auxiliary electrode are connected to each other using the conductive layer 108, but in the second electrode 104 forming step of FIG. 11, when the second electrode is formed of indium tin oxide (ITO), indium zinc oxide (IZO), or the like using the sputtering or the CVD which has an excellent step coverage of a thin film, the auxiliary electrode and the second electrode are connected to each other despite the presence of the barrier rib in the second electrode depositing step. Thus, a subsequent step, i.e., a conductive layer forming step may be omitted. In other words, only in the case where the second electrode depositing method employs a thermal evaporation method having a high linearity, the conductive layer is formed on the second electrode using the sputtering or the CVD, which has an excellent step coverage of a thin film.

In the meantime, FIG. 13 is a view illustrating modifications of the barrier rib. In FIG. 13, other structures of the barrier rib are illustrated as substitutes for an inverted trapezoidal (or tapered) shape which is gradually increased in width as it goes toward the top from the bottom thereof. For example, the barrier rib may be formed in an inverted trapezoidal (or tapered) shape of a two or more-layered structure, or may be formed to have a two or more-layered structure in which a top layer has an overhang shape (i.e., T shape). In this case, in the two or more-layered structure, each layer is formed of the same material and the etch rate is adjusted by controlling the amount of light exposed or an exposure method differently, or each layer is formed of different materials so as to be etched, so that the barrier rib having a multi-layered structure forming various shapes and angles can be made.

Another exemplary embodiment of the present invention will be described hereinafter with reference to accompanying drawings.

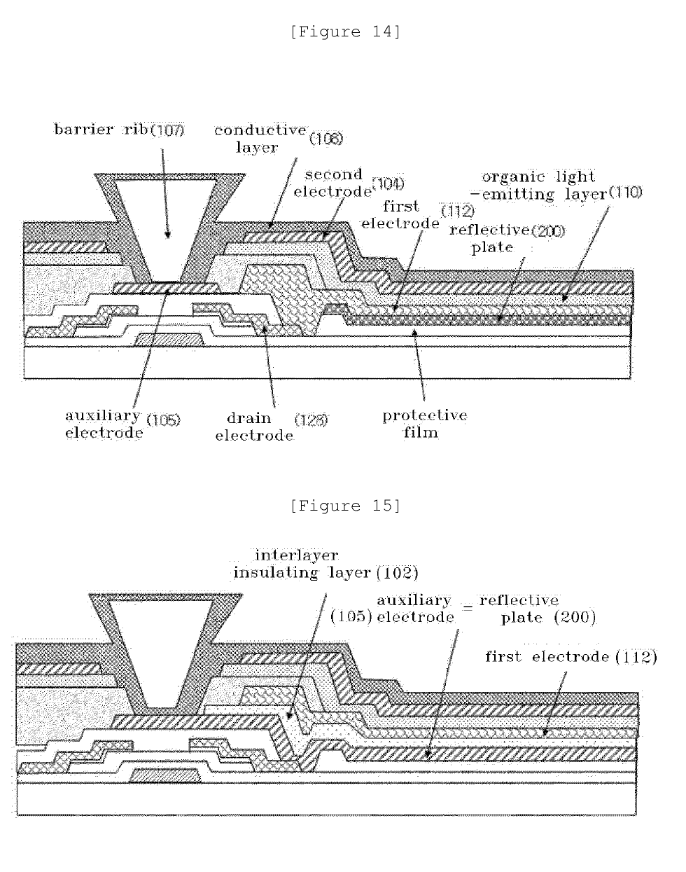

In FIG. 14, a reflective plate 200 is formed beneath the first electrode 112 in order to apply the present invention to a top emission type organic light emitting diode (OLED) display device. Light emitted from the organic light-emitting layer 110 and advancing downward is upwardly reflected from the reflective plate 200. In this case, the second electrode 104 and the conductive layer 108 must be transparent or translucent.

In FIG. 15, in the top emission type organic light emitting diode (OLED) display device which is the same as in FIG. 9, an auxiliary electrode 105 is used as the reflective plate 200 and has a simpler structure than that in FIG. 14. In this structure, the reflective plate 200 as the auxiliary electrode 105 is connected with the second electrode 104 through the barrier rib 107 so that the second electrode is brought into close contact with the first electrode 112. Thus, an interlayer insulating film 201 must be formed between the first electrode and the reflective plate as the auxiliary electrode. At this time, since coherence occurs between two electrode signals by capacitance (i.e., parasitic capacitance) generated from the interlayer insulating film 201 between the first electrode 112 and the auxiliary electrode 105, it is required that the interlayer insulating film 201 should be made thick. The present invention proposes that the interlayer insulating film 201 has a thickness of more than 0.2 μm. In addition, although not shown in FIG. 15, the first electrode 112 is connected with the drain electrode 128.

Since the reflective plate 200 used in FIGS. 14 and 15 must reflect a part of light exiting the organic light-emitting layer 110, it is required that the reflective plate should have a light reflectance of more than 50%, preferably more than 80% in order to minimize loss of light. In addition, in the structure of FIG. 15, light exiting the organic light-emitting layer 110 is transmitted through the interlayer insulating film 201 and is reflected from the reflective plate 200, and then is re-transmitted through the interlayer insulating film 201 toward the top. Thus, the interlayer insulating film 201 has a transmittance of more than 50%, preferably more than 80% in order to minimize loss of light.

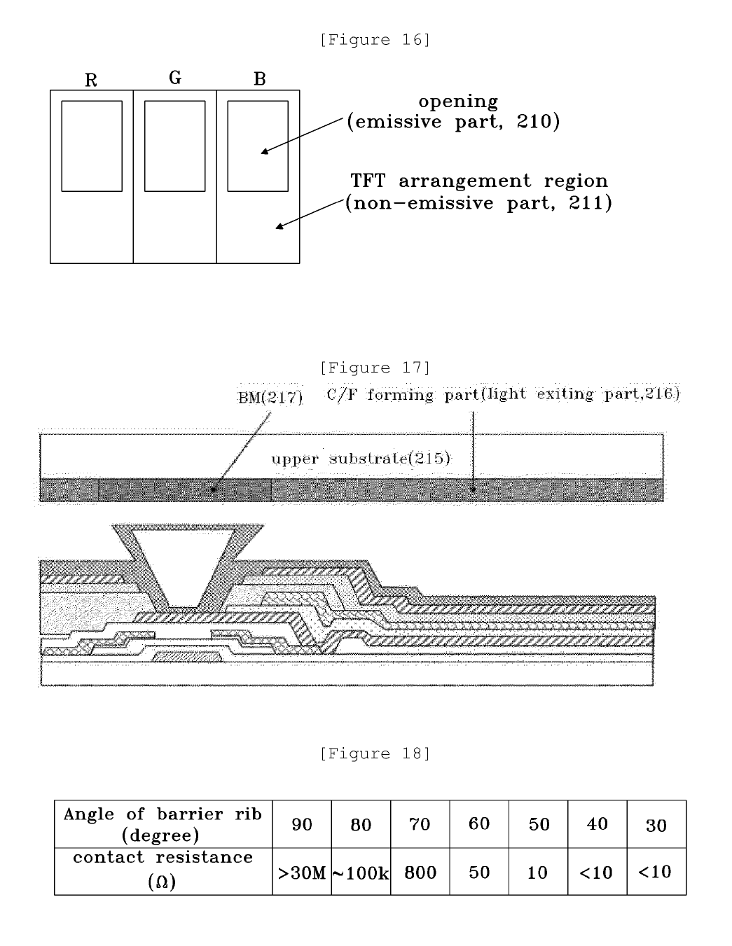

Further, as shown FIG. 16, in the formation of the opening 105a and the barrier rib 107, when a TFT arrangement region 211 as a non-emissive part is used as a substitute for the opening 210 as an emissive part by the organic light-emitting layer 110, a reduction in the aperture ratio by the opening and the barrier rib can be avoided.

Meanwhile, in the top emission type organic light emitting diode (OLED) display device, in the case where a C/F forming part 216 including a color filter (C/F) is formed in an upper substrate 215, as shown in FIG. 17, the opening and the barrier rib may be disposed below a black matrix (BM) positioned between the adjacent color filters to maximize the area of a C/F light exiting part. On the other hand, even in the case where the upper substrate is merely used to protect the organic light emitting diode (OLED) display device in place of the C/F, the opening and the barrier rib may be first disposed below the non-light exiting region to maximize the area of the light exiting part.

FIG. 18 shows a change in the contact resistance according to a taper angle formed by the outer inclined surface of the barrier rib and the top surface of the substrate or the outer inclined surface and the top surface of the barrier rib. It can be seen that the taper angle must be less than 80° in order for a contact resistance of less than 1 kΩ to be obtained between the second electrode 104 and the auxiliary electrode 105 required in the present invention.

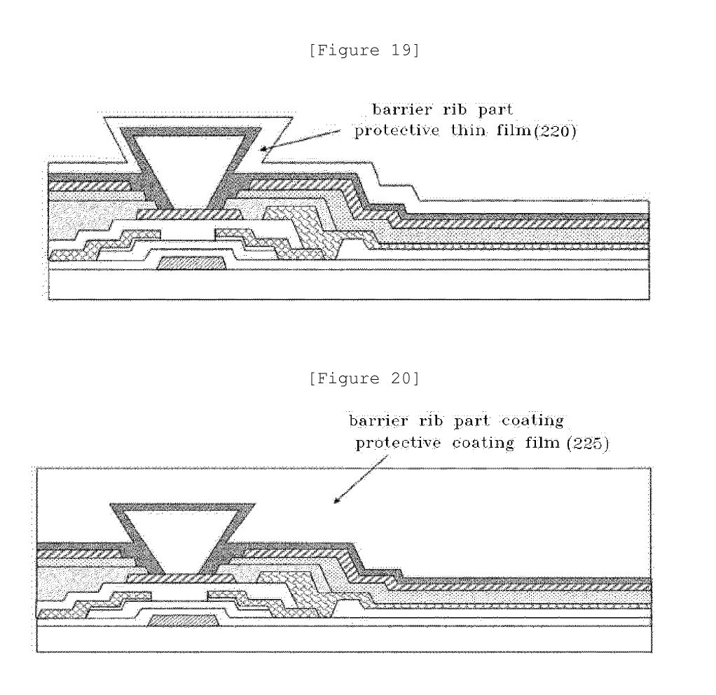

As shown in FIG. 19, preferably, the auxiliary electrode and the second electrode are connected with each other by the conductive layer, and then a protective thin film 220 as an inorganic film, an organic film or an inorganic and organic film, which is formed of a single- or multi-layered structure, is formed on the conductive layer to protect the OLED display device so as to prevent moisture or oxygen from infiltrating into the opening and a side of the barrier rib from the outside of the OLED display device and deteriorating the OLED display device. In addition, as another example, as shown in FIG. 20, a protective coating film 225 may be thickly formed to completely cover the barrier rib.

As such, according to the organic light emitting diode (OLED) display device and the manufacturing method thereof according to the exemplary preferred embodiments of the present invention, the auxiliary electrode 105 contacting with the second electrode 104 is disposed around the driving TFT so that current flowing in the second electrode 104 and the first electrode 112 can be uniformly supplied to the entire area of the OLED display device, thereby obtaining the uniform luminance over the entire area of the OLED display device.

In the meantime, in the present invention, the auxiliary electrode 105 or the reflective plate 200 serving as the auxiliary electrode may be formed of a single metal such as Cu, Al, Ag, Au, Nd, Co, Ni, Mo, Cr, Ti, Pt, or the like, or an alloy thereof. In addition, in the present invention, in the case where the organic light emitting diode (OLED) display device is implemented as a top emission type, it is possible to dispose a circularly polarizing plate or a multilayer film for offsetting external light or improving a contrast ratio at the outside of the second electrode in order to prevent the contrast ratio form being deteriorated by the external light.

As described above, the organic light emitting diode (OLED) display device and the manufacturing method thereof according to the present invention has an advantage in that since a uniform luminance can be ensured for a large-area OLED display device, the quality of a product adopting the same can be increased. In addition, since the inventive OLED display device does not require a conventional separate panel structure or driving means for luminance security, the economic manufacture of the product adopting the same is possible, thereby increasing productivity thereof.

While the present invention has been described in connection with the exemplary embodiments illustrated in the drawings, they are merely illustrative embodiments, and the invention is not limited to these embodiments. It is to be understood by a person having an ordinary skill in the art that various equivalent modifications and variations of the embodiments can be made without departing from the spirit and scope of the present invention. Therefore, various embodiments of the present invention are merely for reference in defining the scope of the invention, and the true technical scope of the present invention should be defined by the technical spirit of the appended claims.

What is claimed is:

1. An organic light emitting diode (OLED) display comprising:
a substrate formed of any one of glass, metal, and plastic;
a thin film transistor (TFT) formed on the substrate for driving the OLED display device;
a display element region consisting of a group of unit pixels, each of which is defined by the intersection of each of data lines and each of gate lines of the thin film transistor (TFT);
a first electrode formed on a top of the driving thin film transistor (TFT);
an auxiliary electrode formed on the substrate;
an opening formed by exposing a part of a top surface of the auxiliary electrode;
a barrier rib formed on the opening of the auxiliary electrode;
an organic light-emitting layer on the first electrode;
a second electrode on the organic light-emitting layer; and
a conductive layer formed on or beneath the second electrode so as to be a part of the second electrode,
whereby the second electrode or the conductive layer is connected with the auxiliary electrode using the barrier rib to reduce a resistance of the second electrode.

2. The OLED display device according to claim 1, wherein the auxiliary electrode is formed between the substrate and the second electrode so as to be as a part of the driving TFT or as an independent wiring.

3. The OLED display device according to claim 1, wherein in the case where the OLED display device is implemented as a top emission type, a reflective plate constituting a part of a top emission element structure is formed beneath the first electrode independently of the auxiliary electrode, or a part of the whole of the reflective plate is used as the auxiliary electrode so as to be connected with the second electrode.

4. The OLED display device according to claim 3, wherein the reflective plate has a light reflectance of more than 50%.

5. The OLED display device according to claim 3, further comprising an interlayer insulating film formed between the auxiliary electrode and the first electrode to reduce an effect of an parasitic capacitance generated between the first electrode 112 and the auxiliary electrode 105.

6. The OLED display device according to claim 5, wherein the interlayer insulating film has a thickness of more than 0.2 μm and a light transmission of more than 50%.

7. The OLED display device according to claim 1, wherein the auxiliary electrode or the reflective plate serving as the auxiliary electrode is formed of a single metal such as Cu, Al, Ag, Au, Nd, Co, Ni, Mo, Cr, Ti, Pt, or the like, or an alloy thereof.

8. The OLED display device according to claim 1, wherein the auxiliary electrode has a sheet resistance of from 0.01 to 50 Ω/sq, and the second electrode as a main electrode has a sheet resistance of from 0.1 to 10 MΩ/sq.

9. The OLED display device according to claim 1, wherein the second electrode and the auxiliary electrode is connected with each other, a contact resistance obtained between the second electrode and the auxiliary electrode is less than 1 kΩ.

10. The OLED display device according to claim 1, wherein in the case where the single second electrode or the second electrode including the conductive layer serves as a cathode, i.e., a negative (−) electrode, it is configured to have a structure including at least one electrode layer whose electron transport material matches with the work function of the cathode, and in the case where the single second electrode or the second electrode including the conductive layer serves as an anode, i.e., a positive (+) electrode, it is configured to have a structure including at least one electrode layer whose hole transport material matches with the work function of the anode.

11. The OLED display device according to claim 1, wherein the opening and the barrier rib is formed over a part or the whole of the pixels of the display element region.

12. The OLED display device according to claim 1, wherein at least one barrier rib is formed on each opening of the auxiliary electrode so as to increase the area of a connection part of the second electrode and the auxiliary electrode to minimize the contact resistance described in claim 9 and increase a contact possibility between the second electrode and the auxiliary electrode.

13. The OLED display device according to claim 1, wherein the opening and the barrier rib are formed at a non-emissive region of the OLED display device.

14. The OLED display device according to claim 1, wherein in the case where the OLED display device is implemented as a top emission type, the opening and the barrier rib are disposed below an upper substrate for the LED display device or below a non-light exiting region of an top protective means for protecting the OLED display device.

15. The OLED display device according to claim 1, wherein the barrier rib is in close contact at a part thereof with the top of auxiliary electrode, and is formed in such a fashion as to be increased gradually in width as it goes toward the top from the bottom thereof.

16. The OLED display device according to claim 1, wherein a taper angle formed by the outer inclined surface of the barrier rib and the top surface of the substrate or the outer inclined surface and the top surface of the barrier rib is less than 80°.

17. The OLED display device according to claim 1, wherein the barrier rib is formed in an inverted trapezoidal (or tapered) shape of a two or more-layered structure, or is formed to have a two or more-layered structure in which a top layer has an overhang shape (i.e., T shape).

18. The OLED display device according to claim 1, wherein the second electrode is deposited using a vacuum deposition equipment including the sputtering, the CVD, or the like, which has an excellent step coverage of a thin film so that the second electrode and the auxiliary electrode are directly connected to each other.

19. The OLED display device according to claim 1, wherein in the case where the second electrode is formed by a thermal evaporation method, or the like, and thus it is not connected to the auxiliary electrode, the conductive layer is formed on the second electrode using a vacuum deposition equipment including the sputtering, the CVD, or the like, so that the second electrode and the auxiliary electrode are indirectly connected to each other.

20. The OLED display device according to claim 1, wherein in the case where the second electrode is formed by a thermal evaporation method, the second electrode is deposited by inclining the substrate such that the second electrode is deposited on the empty space of the barrier rib so as to be connected with the auxiliary electrode.

21. The OLED display device according to claim 1, wherein in the case where the OLED display device is implemented as a top emission type, the second electrode or a multilayered electrode in which the second electrode and the conductive layer are combined has a light transmission of more than 20%.

22. The OLED display device according to claim 1, wherein the auxiliary electrode and the second electrode are connected with each other by the conductive layer, and then an inorganic film, an organic film or an inorganic and organic film, which is formed of a single- or multi-layered structure, is formed on the conductive layer to protect the OLED display device so as to prevent moisture or oxygen from infiltrating into the opening and a side of the barrier rib from the outside of the OLED display device and deteriorating the OLED display device.

23. The OLED display device according to claim 1, wherein in the case where the OLED display device is implemented as a top emission type, a circularly polarizing plate or a multilayer film for offsetting external light or improving a contrast ratio is disposed at the outside of the second electrode in order to prevent the contrast ratio form being deteriorated by the external light.

24. A method for manufacturing an organic light emitting diode (OLED) display device, comprising:
1) forming a substrate formed of any one of glass, metal, and plastic, and a thin film transistor (TFT) formed on the substrate for driving the OLED display device;
2) forming a first electrode on a top of the driving TFT;
3) forming an auxiliary electrode on the substrate and exposing a part of a top surface of the auxiliary electrode to form an opening;
4) forming a barrier rib on the opening of the auxiliary electrode;
5) forming an organic light-emitting layer on the first electrode;
6) forming a second electrode on the organic light-emitting layer; and
7) forming a conductive layer on or beneath the second electrode so as to be a part of the second electrode, if necessary.
